(19) United States
(12) Patent Application Publication
(10) Pub. No.: US 2023/0116216 A1
(43) Pub. Date: Apr. 13, 2023

(54) SIMULATION DEVICE, SIMULATION SYSTEM, CONVEYANCE SYSTEM, AND SIMULATION METHOD

(71) Applicant: HITACHI INDUSTRIAL PRODUCTS, LTD., Tokyo (JP)

(72) Inventors: Hiroshi YOSHITAKE, Tokyo (JP); Ryota KAMOSHIDA, Tokyo (JP); Yoshikazu NAGASHIMA, Tokyo (JP)

(21) Appl. No.: 17/795,896

(22) PCT Filed: Nov. 19, 2020
(86) PCT No.: PCT/JP2020/043166

§ 371 Date: Jul. 28, 2022

(30) Foreign Application Priority Data
Feb. 6, 2020 (JP) 2020-018888

(51) Int. Cl. G01C 21/20; G06F 30/20

(52) U.S. Cl. CPC G01C 21/206; G06F 30/20

(57) ABSTRACT

A simulation device (800) comprises: a simulation unit (803) which performs simulation of the movements of a plurality of moving bodies on a path; a storage unit (802) which retains an estimated decrement that is an indicator of change over time in the congestion level of the plurality of moving bodies on the path; a first calculation unit (805) which calculates, on the basis of the simulation results, the congestion level of the plurality of moving bodies on the path; and a second calculation unit (806) which calculates the indicator of change over time in the congestion level that was calculated by the first calculation unit. A suitable decrement can be set such that the estimated decrement in congestion level, that is used as a simulation input, and the decrement in the congestion level in the simulation results are equal.

### CLAIM OF PRIORITY

The present application claims priority from Japanese patent application JP2020-18888 filed on Feb. 6, 2020, the content of which is hereby incorporated by reference into this application.

### BACKGROUND

The present invention relates to a system for simulating movement of a plurality of moving bodies and a technique to control a movement method.

In distribution warehouses and factories, equipment used for conveyance and cargo handling work has been automated, and the control technique for realizing more efficient movement of a plurality of pieces of automated equipment in carrying out a conveyance task and the like has been actively developed. In distribution warehouses and factories, picking work is performed where workers collect items stored in the warehouse or factory in accordance with a shipping order, and sort those items based on shipping addresses. Examples of the picking work using automated equipment include a picking system in which an automated guided vehicle conveys a storage rack having items stored therein to a work station where a worker picks items corresponding to a shipping order from the storage rack conveyed by the automated guided vehicle.

Japanese Patent Application Laid-open Publication No. 2017-30972 (Patent Document 1) discloses a technique to carry out a picking system using automated guided vehicles. In order to convey a storage rack to a worker, the automated guided vehicle goes directly under the storage rack. Then the automated guided vehicle pushes up the lower shelf of the storage rack from below, lifting the storage rack, and conveys the storage rack while keeping it up. The worker waits for the storage rack at the work station, where items are to be taken out. After the storage rack arrives at the work station, the worker carries out a picking task for each shipping order by taking out items corresponding the shipping order, and loading them into a designated spot or box for the shipping address corresponding to the shipping order, out of a plurality of spots/boxes for respective shipping addresses, based on the quantity specified by the shipping order. After the picking task is completed, the automated guided vehicle takes the storage rack out of the work station. The embodiments of Patent Document 1 disclose a configuration where the automated guided vehicle considers the current congestion level, the past traffic trend, the task priority and/or other types of appropriate information in selecting the best route to a destination.

In addition, with the recent advancement of the automatic driving technology and railroad network, the operation control technology for automobiles and other types of vehicles that aims at suppressing or mitigating traffic congestion is receiving attention. Japanese Patent Application Laid-open Publication No. 2018-136781 (Patent Document 2) discloses an invention to mitigate traffic congestion in accordance with the likelihood and status of the traffic congestion. According to the embodiments of Patent Document 2, how the congestion peak percentage will change in the future is predicted based on a change in congestion peak percentage over a prescribed period of time in order to predict the size of congestion.

### SUMMARY OF THE INVENTION

However, Patent Documents 1 and 2 have several challenges. For example. In finding a route for each moving body based on the congestion state and simulating a behavior that can mitigate traffic congestion gradually from the time at which the route was found, it is not easy to determine what value the reduction rate would take, which provides a mitigation amount of the congestion level per unit time.

For the control technique of a situation where a plurality of moving bodies exist, the system is often examined through an effect study based on simulation because it would be costly to examine the system using actual machines. Also, in an operation with actual machines, the congestion state and traffic volume due to the movement of a plurality of moving bodies are sometimes predicted based on simulation through modeling. The estimated reduction rate that simulates mitigation of the congestion level in an environment with a plurality of moving bodies is preferably determined by performing trials through simulation in advance.

To solve at least one of the foregoing problems, provided is a simulation device, comprising: a simulation unit that performs a simulation of movement of a plurality of moving bodies each moving along a route; a storage unit that stores therein an estimated reduction rate that is an index representing a change over time in congestion level of the route of each of the plurality of moving bodies; a first calculation unit that calculates a congestion level of the route of each of the plurality of moving bodies based on a result of the simulation; and a second calculation unit that calculates an index representing a change over time in congestion level calculated by the first calculation unit.

According to one aspect of the present invention, it is possible to set an appropriate reduction rate such that an estimated reduction rate of a congestion level used for an input of simulation and a reduction rate of a congestion level in the simulation result are the same as each other. This allows for improvement of the efficiency of the conveyance system subjected to simulation. Challenges, configurations, and effects other than those described above will become apparent in the descriptions of embodiments below.

### BRIEF DESCRIPTIONS OF THE DRAWINGS

FIG. 1 is a schematic diagram illustrating an example of the operation environment of moving bodies subjected to simulation of a simulation device of an embodiment of the present invention.

FIG. 2 is a block diagram illustrating an example of the entire configuration of a conveyance system subjected to the simulation of the simulation device of an embodiment of the present invention.

FIG. 3A and FIG. 3B are block diagrams illustrating an example of a hardware configuration of an operation management device and an order management device employed in the simulation of an embodiment of the present invention.

FIG. 4 is a diagram for explaining an example of a picking instruction data for picking work subjected to the simulation of this embodiment of the present invention.

FIG. 5 is a flowchart showing an example of how the operation management device generates a travel route for an automated guided vehicle and control it to move in this embodiment of the present invention.

FIG. 6A and FIG. 6B are diagrams for explaining an example of a user interface for determining an estimated reduction rate in an embodiment of the present invention.

FIG. 7 is a diagram for explaining an example of a user interface for displaying results of performing the simulation in an embodiment of the present invention.

FIG. 8 is a diagram for explaining an example of the functional configuration and processes of the simulation device in an embodiment of the present invention.

### DETAILED DESCRIPTION OF THE EMBODIMENTS

Next, embodiments of the present invention will be explained in detail with reference to figures.

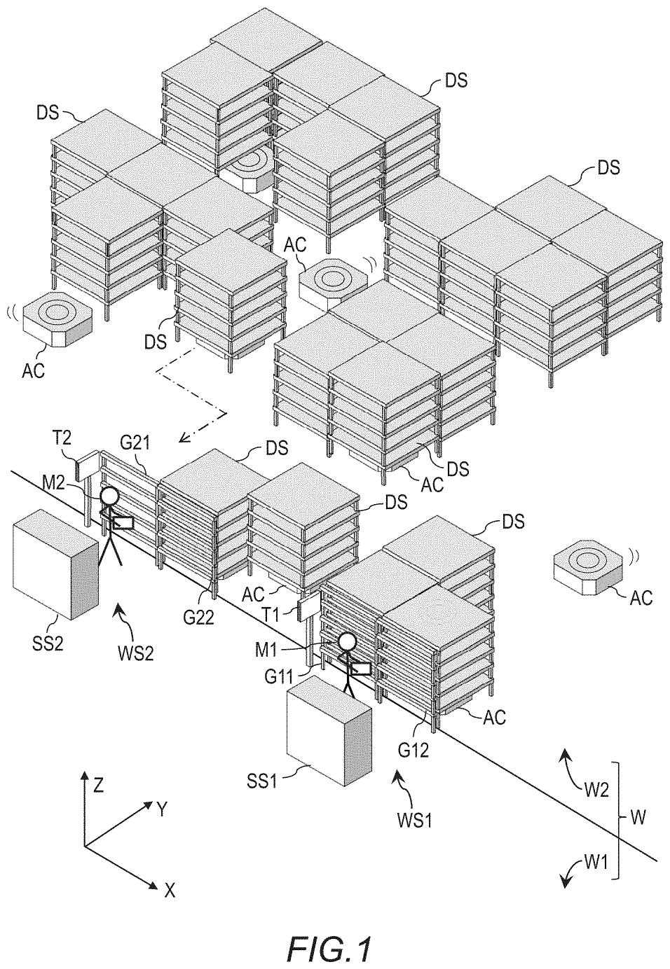

FIG. 1 is a schematic diagram illustrating an example of the operation environment of moving bodies subjected to simulation of a simulation device of an embodiment of the present invention.

One example of moving bodies in the present invention is an automated guided vehicle that conveys items in a distribution warehouse or factory. FIG. 1 illustrates automated guided vehicles AC conveying items in a warehouse W. The warehouse W has a working area W1 and a storage area W2. The storage area W2 includes a plurality of storage racks DS. Each storage rack DS contains at least one kind of items. In the storage area W2, there are a plurality of automated guided vehicles AC. In this example, the automated guided vehicles AC have the function of conveying the storage rack DS.

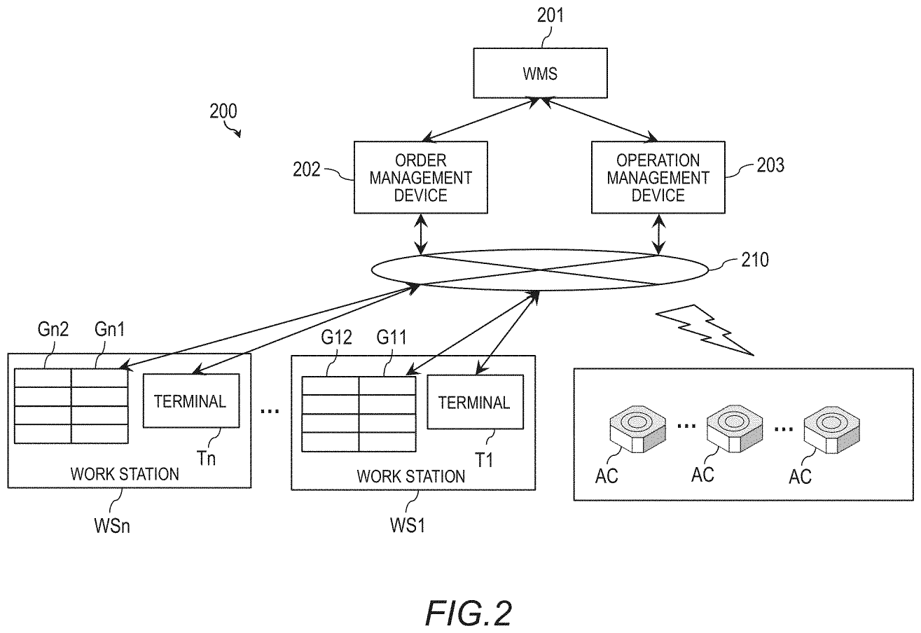

The floor surface of the storage area W2 is divided into small areas by a two-dimensional grid, for example, and WMS201 and an operation management device 203, which are illustrated in FIG. 2 described later, manage the position of each automated guided vehicle AC and storage rack DS by the coordinates of the center of each grid (that is a rectangular section). The positions of the automated guided vehicle AC and the storage rack DS may also be managed by the coordinates of a vertex, instead of the coordinates of the center of each grid. Each grid has a coordinate maker including the coordinates of the grid. The coordinate marker is a barcode (including a two-dimensional code) placed or painted on the grid, for example. The barcode is information including the coordinates of the grid.

The working area W1 includes a plurality of working stations WSi including those denoted with WS1 and WS2. In this embodiment, picking work is performed at the work station WSi, and therefore, the work station may also be referred to as a picking station. Here, i is the number of the work station WS, and an integer satisfying 1≤i≤n. n is an integer of 2 or greater, and indicates the total number of work stations WS. In this embodiment, n=2.

When it is not necessary to distinguish one work station WSi from other work stations WSi, such as when a description applies to all of the work stations WSi, the work stations will collectively be referred to as the work station WS. A work station WSi includes a gate Gij, a terminal Ti, and a sorting rack SSi. Here, i is the number of the work station WS. Also, j in the gate Gij is an integer satisfying 1≤j≤m, indicating the number of the gate Gi included in each work station WS. In this embodiment, m=2.

That is, each work station WSi has one terminal Ti, one sorting rack SSi, and m number of gates G. If individual gates Gij, terminals Ti, and sorting racks SSi do not need to be distinguished, they will be referred to as gates G or Gij, terminals T or Ti, and sorting selves SS or SSi as necessary. The gate Gij is an arriving point of the storage rack DS. One gate Gij corresponds to one storage rack DS. The terminal Ti displays a list of shipping addresses of items (information associating items with sections of the sorting rack SSi) and the like.

The sorting rack SSi placed in the working station WSi is a rack where items are placed after being picked up from the storage rack DS via the gate Gij. Here, i in a worker Mi is the number of the work station WS, and an integer satisfying 1≤i≤n. n is an integer of 2 or greater, and indicates the total number of work stations WS. In this embodiment, n=2. When it is not necessary to distinguish each worker Mi, the worker will be referred to as worker(s) M or Mi as needed.

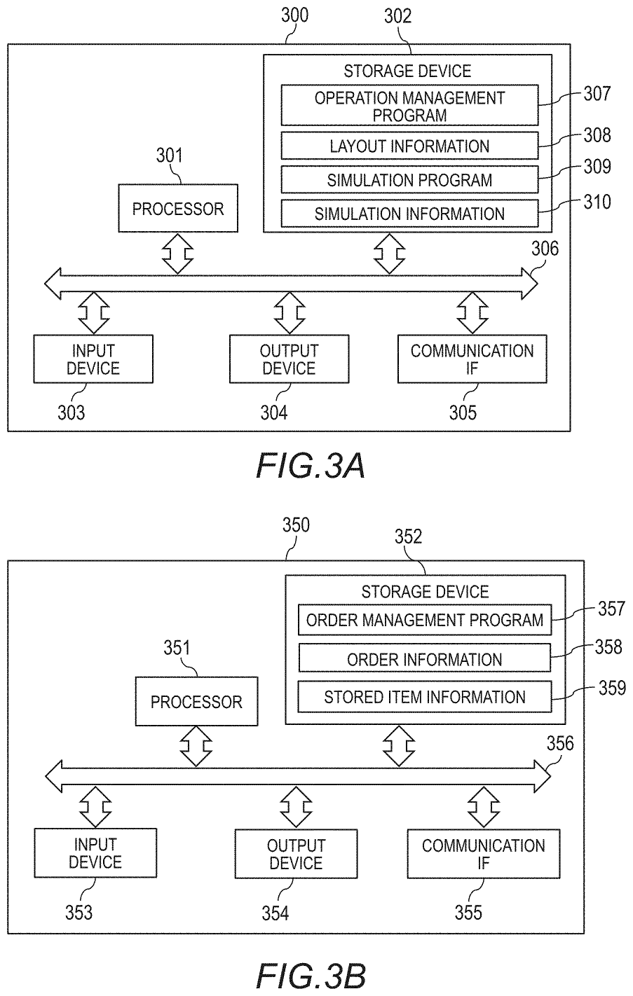

The automated guided vehicle AC conveys the storage rack DS, following the steps described below. First, the automated guided vehicle AC moves to the position of the designated storage rack DS. The automated guided vehicle AC goes directly under the designated storage rack DS, and upon receiving lift-up instruction information from the operation management device 203 illustrated in FIG. 3, lifts the storage rack DS straight up by a jack mechanism installed on the top surface of the automated guided vehicle AC (not shown in the figure). Then the automated guided vehicle AC moves to the designated working station WS in the working area W1, while keeping the storage rack DS lifted up. When arriving at the work station WS, the automated guided vehicle AC lowers the storage rack DS to the floor. After the worker M completes the picking work, the automated guided vehicle AC lifts up the storage rack DS again, and brings the storage rack DS back to its original place.

FIG. 2 is a block diagram illustrating an example of the entire configuration of a conveyance system subjected to the simulation of the simulation device of an embodiment of the present invention.

The conveyance system 200 includes a WMS (warehouse management system) 201, an order management device 202, an operation management device (control part) 203, automated guided vehicles AC, terminals Ti, a gate control device (not shown), and gates Gij. The WMS 201 is connected to the order management device 202 and the operation management device 203 such that the respective devices can communicate with each other. The order management device 202, the operation management device 203, the automated guided vehicles AC, the terminals Ti, and the gate control device Gc can communicate with each other via a network 210. At least the automated guided vehicle AC is connected to the operation management device 203 such that wireless communication is possible via the network 210.

The WMS 201 controls the order management device 202 and the operation management device 203. Specifically, the WMS 201 transmits an order and storage data of the storage rack to the order management device 202. The order is information including names, quantities, and shipping addresses of the items to be picked. The storage data of the storage rack is data regarding the storage rack DS where the items are stored. Specifically, the storage data of the storage rack includes the name and quantity of items stored in each storage rack DS, identification information of the storage rack DS where a particular item is stored, and positional information of the storage section where a particular item is stored (identification information of a rack surface, a section level, and a section row to which the storage section belongs, for example).

Also, the WMS 201 links processes at the order management device 202 to processes at the operation management device 203. For example, upon receiving a notification indicating the worker M (see FIG. 1) has completed the picking task of items from the order management device 202, the WMS 201 sends an instruction to the operation management device 203 to bring the storage rack DS back to the original place.

The operation management device 203 manages the operation of the automated guided vehicle AC (such as conveyance of a storage rack DS by the automated guided vehicle AC). The automated guided vehicle AC has a reading device (not shown) such as a visible light camera or an infrared camera at the bottom of the body, and scans the floor surface while moving. If the coordinate marker on the floor surface is a bar code, for example, the reading device is a bar-code reader. When passing through a grid having a coordinate marker, the reading device scans the bar-code indicating the coordinates, which allows the automated guided vehicle AC to acquire the coordinates. The automated guided vehicle AC transmits the acquired coordinates to the operation management device 203. This way, the operation management device 203 manages the current position of each automated guided vehicle AC.

Upon receiving conveyance instruction information for a storage rack DS from the order management device 202 via the WMS 201, the operation management device 203 identifies the storage rack DS that has the items to be shipped, and the work station WSi that has the sorting rack SSi including a sorting rack section for the shipping address of the items to be shipped. Then the operation management device 203 acquires the position of the identified storage rack DS, and generates route information from that position to the position of the identified work station WSi. At this time, the operation management device 203 sends route information to an automated guided vehicle AC that is closest to the identified storage rack DS, and instructs the automated guided vehicle AC to move according to the route information.

FIG. 3A is a block diagram illustrating an example of a hardware configuration of the operation management device 203 employed in the simulation of an embodiment of the present invention. FIG. 3B is a block diagram illustrating an example of a hardware configuration of the order management device 202 employed in the simulation of an embodiment of the present invention.

The operation management device 203 of this embodiment may be realized by hardware of a computer 300 illustrated in FIG. 3A. The computer 300 includes a processor 301, a storage device 302, an input device 303, an output device 304, and a communication interface (communication IF) 305. The processor 301, the storage device 302, the input device 303, the output device 304, and the communication IF 305 are connected to each other via a bus 306.

The processor 301 controls the computer 300. The storage device 302 is a working area of the processor 301. The storage device 302 is a non-temporary or temporary storage medium that stores various types of programs and data. Examples of the storage device 302 include ROM (read only memory), RAM (random access memory), HDD (hard disk drive), and a flash memory.

In the storage device 302 of the computer 300 that acts as the operation management device 203 of this embodiment, an operation management program 307, layout information 308, a simulation program 309, and simulation information 310 are stored. The processes performed by the operation management device 203 in this embodiment are actually performed by the processor 301 controlling the input device 303, the output device 304, the communication interface 305, and the like as necessary according to the operation management program 307 or the simulation program 309.

The layout information 308 includes at least information regarding the layout of various objects in the storage area W2. For example, the layout information 308 may include information such as the position of each storage rack DS in the storage area W2, the orientation (which rack side is facing which direction) of each storage rack DS, items stored in each storage section of each storage rack DS, the position of each automated guided vehicle AC, the position of each gate G, the direction of each gate G, and routes for the automated guided vehicle AC to take after lifting up the storage rack DS.

The simulation information 510 includes information referenced in the simulation performed by the processor 301 in accordance with the simulation program 306, and information generated as a result of the simulation. As described later, the information referenced in the simulation may include layout information, the initial position of each automated guided vehicle AC, the initial value of the estimated reduction rate, and instruction data. The layout information included in the simulation information 510 may be a copy of at least a part of the layout information 308. The estimated reduction rate and instruction data will be described later. The information generated as a result of simulation may include the position of each automated guided vehicle AC at each timing, for example, and may include the congestion level at each timing and at each position inside the warehouse W, which is calculated based on the position of each automated guided vehicle AC at each time, and the estimated reduction rate calculated based on the congestion level at each timing.

The input device 303 inputs data. Examples of the input device 303 include a keyboard, a mouse, a touch panel, number keys, and a scanner. The output device 304 outputs data. Examples of the output device 304 include a display and a printer. The communication IF 305 is connected to the network 210 to receive and transmit data.

The order management device 202 of this embodiment may be realized by the hardware of the computer 350 illustrated in FIG. 3B. The computer 350 includes a processor 351, a storage device 352, an input device 353, an output device 354, and a communication interface (communication IF) 355. The processor 351, the storage device 352, the input device 353, the output device 354, and the communication IF 355 are connected to each other via a bus 356.

The processor 351 controls the computer 350. The storage device 352 is a working area of the processor 351. The storage device 352 is a non-temporary or temporary storage medium that stores various types of programs and data. Examples of the storage device 352 include ROM (read only memory), RAM (random access memory), HDD (hard disk drive), and a flash memory.

In the storage device 352 of the computer 350 that acts as the order management device 202 of this embodiment, an order management program 357, order information 358, and stored item information 359 are stored. The processes performed by the order management device 202 in this embodiment are actually performed by the processor 351 controlling the input device 353, the output device 354, the communication interface 355, and the like as necessary according to the order management program 357.

The order information 358 at least includes information of items and shipping addresses for shipping, receiving and delivery of various types of items. For example, the order information 358 may include information such as the type of the item to be picked up from the items stored in this system for delivery, the name of the item, the store name and address to which the item will be shipped, the type, quantity and name of items to be stored in the storage rack of this system, and the rack ID, rack surface, and section of the storage rack from which the item is to be picked up for delivery.

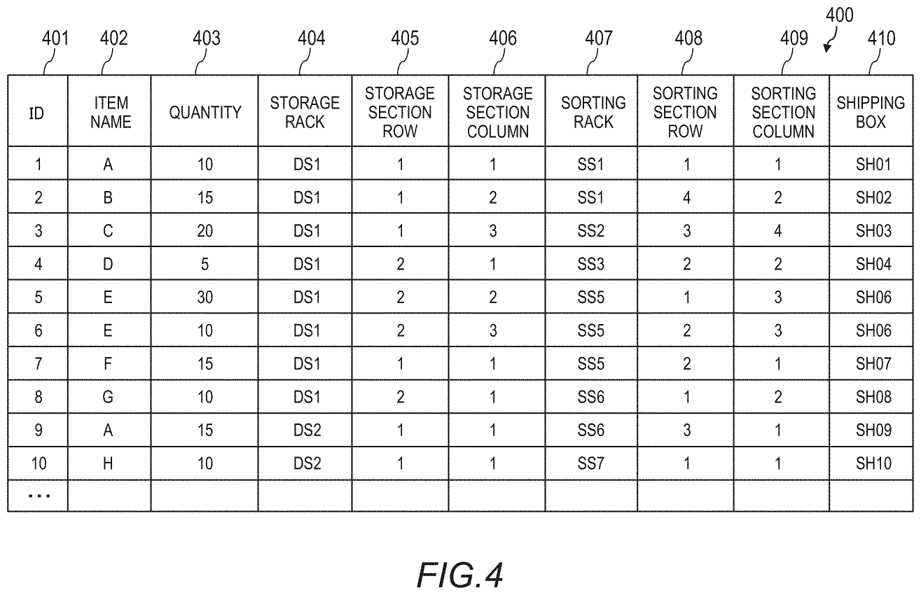

FIG. 4 is a diagram for explaining an example of the picking instruction data for picking work subjected to the simulation of this embodiment of the present invention.

This picking instruction data 400 is included in the simulation information 310, and a unique collection of an instruction data ID 401, a name 402 of an item necessary for delivery, a quantity 403 of the item, an ID 404 of a storage rack DS having that item, a section row 405 and a section column 406 at which the item is stored, an ID 410 of a shipping box corresponding to the shipping address, an ID 407 of a sorting rack SS having that shipping box, section row 408 and section column 409 of the sorting rack SS. Thus, in this embodiment, the storage rack DS and the sorting rack SS for the picking work are associated with each other in advance, and after selecting the automated guided vehicle AC that conveys the storage rack DS, the instruction for conveyance is issued in the simulation.

This picking instruction data 400 may be generated based on an actual order and an actual placement of items that are identified from the order information 358 and the stored item information 359 held by the order management device 202, or may be generated solely for the simulation regardless of an actual order and the like. The order management device 202 gives such picking instruction data 400 to the operation management device 203 as a conveyance task. Alternatively, the operation management device 203 may generate this type of conveyance task.

FIG. 4 illustrates picking instruction data 400 for simulation, but picking instruction data for the actual warehouse operation is also populated in the same format as that of FIG. 4. For example, picking instruction data is generated based on the order information 358 and the stored item information 359 held by the order management device 202, and an actual conveyance task is given for the automated guided vehicle AC based on that data.

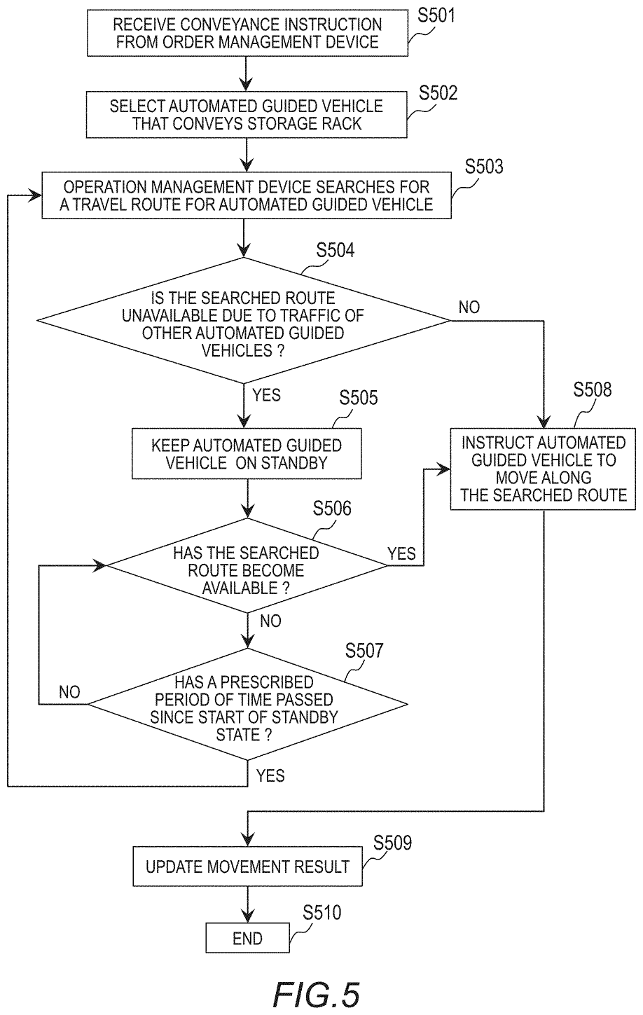

FIG. 5 is a flowchart showing an example of how the operation management device 203 generates a travel route for the automated guided vehicle AC and control it to move in this embodiment of the present invention.

When the order management device 202 gives a rack conveyance task to the automated guided vehicle AC based on a storage and delivery instruction, the operation management device 203 receives the conveyance task (S501), and selects an automated guided vehicle AC to convey the storage rack DS corresponding to the conveyance task (S502). The operation management device 203 generates a travel route from the current position of the automated guided vehicle AC to the destination (S503), and gives the automated guided vehicle AC a command to move. The estimated reduction rate is used for route finding in generating a route to simulate a reduction in congestion over time in routes subjected for calculation based on the recent congestion status, in order to figure out how long it takes for the automated guided vehicle AC to move along possible routes.

For example, the operation management device 203 may use the estimated reduction rate set at that time to calculate the congestion level of routes that would be reduced due to the time lapse, and find a route that incurs a minimum cost based on the cost for the calculated congestion level (the higher the congestion level is, the higher the cost gets, for example). The calculation of the congestion level based on the estimated reduction rate will be described in further detail later (Formula 1 and the like).

When the estimated reduction rate is determined based on the simulation of this embodiment, a special conveyance situation where starting points, end points, and travel routes of the automated guided vehicle AC are significantly uneven in a travel environment (will be referred to as a layout below) of the automated guided vehicle AC is not preferable in the simulation of the traffic status of the overall layout. By using a task for conveying a randomly-selected rack in the layout to a randomly-selected work station WS as one example of the rack conveyance task given from the order management device 202 to the automated guided vehicle AC, it is possible to evaluate the congestion level taking into consideration the traffic status of the overall layout, which makes it possible to find an appropriate estimated reduction rate.

When the number of components used for the actual operation such as racks, work stations WS, and automated guided vehicles AC is smaller than that of actual components placed in the layout, a random conveyance task generated by removing unused components for the simulation can be used to find an appropriate reduction rate in a limited layout.

In another example, if the inventory status of a storage rack DS and picking work at the working station WS corresponding to the storage rack DS are known before the actual operation, it is possible to determine a reduction rate adjusted for each operation by setting up a conveyance task that conveys the storage rack DS needed for the known picking work.

Next, the operation management device 203 determines whether or not the route found for the automated guided vehicle AC is reserved for the scheduled movements of other automated guided vehicles AC or not (S504). The operation management device 203 reserves a route that each automated guided vehicle AC is scheduled to take, so that other automated guided vehicles AC do not enter the route and a collision of automated guided vehicles AC can be prevented. This reservation is cleared after the scheduled automated guided vehicle AC has moved down the route. In S504, the operation management device 203 determines whether or not the route found for the automated guided vehicle AC is reserved for other automated guided vehicles AC.

If the searched route is not available (S504: Yes), the operation management device 203 keeps the automated guided vehicle AC on standby until the searched route becomes available (S505). After that, the operation management device 203 determines whether the searched route has become available, or in other words, the reservation has been cleared (S506). If the searched route is not yet available (S506: No), the operation management device 203 determines whether a prescribed amount of time has passed since the stand-by state started (S507). If a prescribed amount of time has not passed since the stand-by state started (S507: No), the operation management device 203 returns to S506 and determines whether the searched route has become available. If a prescribed amount of time has passed since the standby state started (S507: Yes), the operation management device 203 returns to S503 and searches for another route for the automated guided vehicle AC.

If the searched route is available (S504: No or S506: Yes), the operation management device 203 instructs the automated guided vehicle AC to move down the searched route (S508). Next, the operation management device 203 updates the travel result of the automated guided vehicle AC. For example, the operation management device 203 may calculate the position of the automated guided vehicle AC at each point in time between the start of the move along the route upon instruction and the end of the move, the time at which the automated guided vehicle started to move upon receiving the instruction, the time at which the automated guided vehicle has completed the move, and the like based on the moving speed of the automated guided vehicle AC, and add the calculation results to the simulation information 310. As described below, the congestion level in simulation can be calculated based on this travel result. After that, the process is concluded (S510).

The process described above is a process for generating a travel route of the automated guided vehicle AC and controlling it to move in a simulation, but the same process can be employed for generating a travel route of the actual automated guided vehicle AC and controlling it to move in order to carry out a conveyance task based on an actual order. In this case, the travel result may be updated (S509) based on the position of the actual automated guided vehicle AC.

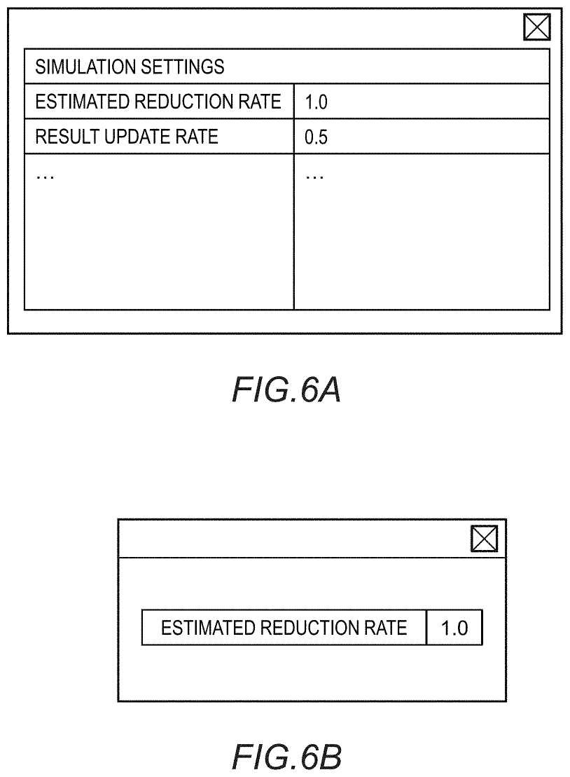

FIG. 6A and FIG. 6B are diagrams for explaining an example of a user interface for determining an estimated reduction rate in an embodiment of the present invention.

A user who uses the simulation device according to this embodiment may input the estimated reduction rate as a numerical value through a screen on an electronic terminal. As illustrated in FIG. 6A, the estimated reduction rate may be one of the settings displayed on the same window as other setting variables (such as the result update rate) used for the simulation of this embodiment, or as illustrated in FIG. 6B, the estimated reduction rate may be set on a standalone window that opens up when any setting button on the UI for simulation setting is clicked on the terminal. In another embodiment, setting values given by the user may be passed onto a simulator by loading a text file including the estimated reduction rate and other setting values representing the variables used for the simulation.

The estimated reduction rate may be given to the simulator by the user as not only a fixed numerical value, but also a specific numerical range, and additionally, it is also possible to set an interval to the numerical range, and perform a comprehensive simulation by repeating a simulation as many times as indicated by the different values of the estimated reduction rate. Also, if the estimated reduction rate is defined in the simulator by a linear/non-linear function, it is possible to provide a factor of the function. If there is a particular spot that is likely to have a higher level of congestion depending on the layout, it is possible to have different setting values of the estimated reduction rate for respective areas or routes. The provision method of the estimated reduction rate may be a combination of any of the above-mentioned methods.

Examples of the route-finding method for the automated guided vehicle AC calculated by the operation management device 203 include selecting, from a plurality of possible waypoints, locations that allow for the shortest possible travel time to the end point. In this process, if the coordinates of the current position are o, the coordinates of a possible waypoint are v, and the coordinates of the end point is d, the travel time from the current position o to the end point d via the waypoint v is Qo(v,d), and Qo(v,d) for all of the routes can be managed in the form of a table. There are a plurality of possible waypoints v that are reachable from the current position o. For example, if the positions are represented by (X,Y) coordinates in a two-dimensional grid, v from o can be a group of coordinates having either X or Y in common, and reachable with one linear movement. However, in the linear movement, the automated guided vehicle AC may rotate its body to move from the current position o toward the direction of v.

As one example, Qo(v,d) takes, as the initial value, the shortest time calculated based on the driving performance of the automated guided vehicle AC such as acceleration and maximum speed, and by updating this value based on the travel result, it is possible to simulate the traffic on the layout during the operation of the conveyance system subjected to this simulation while reflecting the congestion status in the simulation. Examples of reflecting a reduction in congestion level into Qo(v,d) using the estimated reduction rate includes correcting the travel time by Formula (1) below.

Q′o(v,d)=max(Qo(v,d)−β·(t−t0),Qo(v,d)min) (1)

In this formula, the variable β is the estimated reduction rate given as a numerical value, the variable t is the time at which the operation management device 203 performs route finding, the variable t0 is the last time when Qo(v,d) was updated by the travel result of the automated guided vehicle AC, and Qo(v,d)min is the shortest travel time when the automated guided vehicle moved without stopping due to congestion, which is obtained from the driving performance of the automated guided vehicle. The waypoint can be determined based on Q′o(v,d) taking into consideration the reduction in congestion, by subtracting a longer travel time of a case in which congestion occurs as indicated by the estimated reduction rate β from the estimated travel time from the current position o to the end point d via the waypoint v obtained from the travel result of the automated guided vehicle AC. The estimated reduction rate can be defined as a table Bo (v,d) including the current location o, the possible waypoints v, and the end point d according to the travel schedule, instead of the scalar value β.

Other route-finding methods include the Dijkstra method, A*method, and the search method when the coordinate points on the layout by the dynamic programming method are regarded as a graph. Even with any of those methods, it is possible to calculate a route with reduced congestion using the estimated reduction rate. In this case, by introducing the estimated reduction rate to the link cost associated with the movement on a route between the coordinate points, and calculating the cost associated with the movement between the coordinate points in a manner similar to Formula (1), the optimal route in case congestion is eventually reduced after the calculation time at which the operation management device 203 performed the route-finding can be calculated as a route with a minimum cost.

The description above is for simulation, but the similar route-finding process is performed for generating a travel route of the actual automated guided vehicle AC for carrying out a conveyance task based on an actual order. It is preferable that a route-finding algorithm used in the simulation be the same as a route-finding algorithm used for generating a travel route of the actual automated guided vehicle AC.

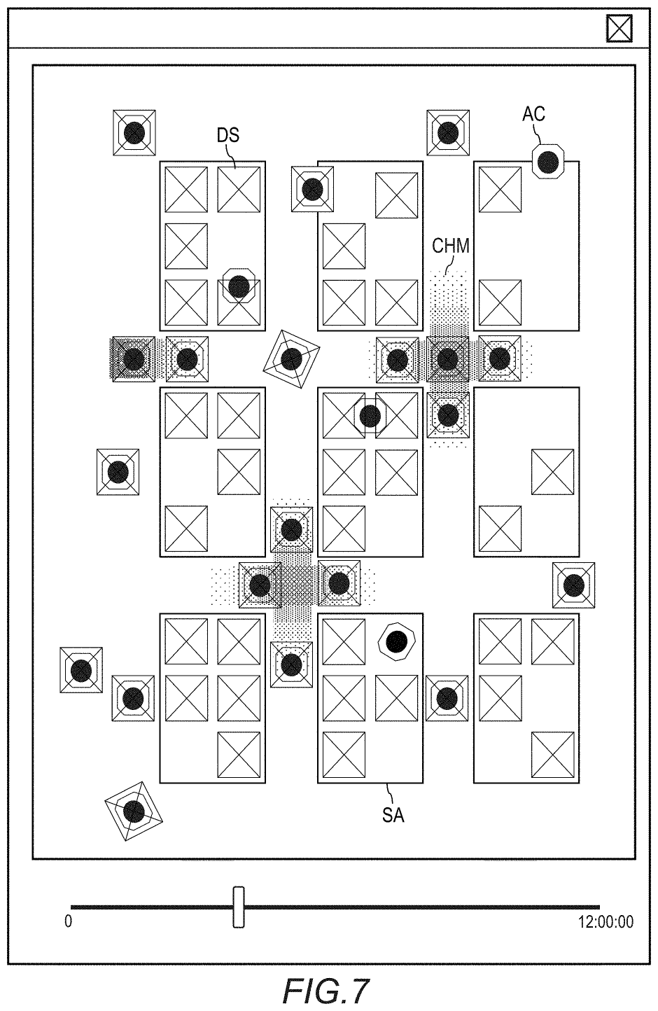

FIG. 7 is a diagram for explaining an example of a user interface for displaying results of performing the simulation in an embodiment of the present invention.

Specifically, FIG. 7 illustrates one example of an application screen displayed on an electronic terminal including the simulation device of this embodiment. However, it is also possible to store the results of the simulation of this embodiment in the form of an output file or the like, and load the output file or the like as an application installed in another terminal for display.

FIG. 7 is a bird's-eye view of the layout when viewed from the top of the site, illustrating automated guided vehicles AC in the layout, racks DS placed in the rack storage area SA as well as being carried by automatic guided vehicle AC, work stations WS (not shown in FIG. 7), and passages as examples. The present invention is not limited to the example of FIG. 7, and the layout may also be represented as three-dimensional CG. In addition, as the components of the layout to be displayed, charging stations of the automatic guided vehicles AC, picking workers, picking work areas, a post-process area where the items are transported after picking, and an area where items included in the layout are pre-processed may also be included.

In order to notify the user of the congestion status of the automatic guided vehicles AC, the user interface shown in FIG. 7 can display a heat map CHM superimposed on the layout to indicate the congestion level of the automatic guided vehicles AC. The congestion level may be calculated based on the number of automated guided vehicles AC that comes down a path between two coordinate points of choice per unit time, a period of time required for one automated guided vehicle AC to finish traveling, or the like. For example, the congestion level may be calculated such that the smaller the number of automated guided vehicles AC that have moved down between two coordinate points of choice per unit time is, the greater the congestion level gets, or such that the longer one automated guided vehicle takes to finish traveling, the greater the congestion level gets. These methods may also be combined for the calculation.

In addition to the congestion level based on the actual movement in the simulation (hereinafter referred to as “actual congestion level”), the estimated congestion level estimated based on the estimated reduction rate in finding a route for the automatic guided vehicle during the simulation may be displayed as a simulation result. At this time, the estimated congestion level can be displayed on the heat map in the same way as the actual congestion level. As an example, by using a color map having a different color scheme from the heat map CHM showing the actual congestion level, it is possible to compare the estimated level in the simulation and the actual congestion level to understand a discrepancy between the two.

The user of the simulation device according to an embodiment of the present invention can set the estimated reduction rate to an appropriate value that is unlikely to cause congestion of the automated guided vehicles AC by adjusting the estimated reduction value as an input for the simulation, while comparing the two types of congestion levels described above. This way, the conveyance system of the automated guided vehicles AC subjected to the simulation allows items to be conveyed in a shorter period of time, which makes possible the effect of improved work efficiency as a picking system.

In order to prevent the visual representation of the heat maps from being too busy as a result of displaying the two types of heat maps at the same time, it is also possible to display a difference between the estimated congestion level and the actual congestion level from the simulation as a heat map. This makes it possible to identify areas where the difference between the two is larger based on one type of heat map.

In the example described above, the heat map was shown as an example of the method of displaying the congestion distribution in the space where the automatic guided vehicles AC travel (that is, the space to be simulated), but the congestion distribution may be displayed by other methods.

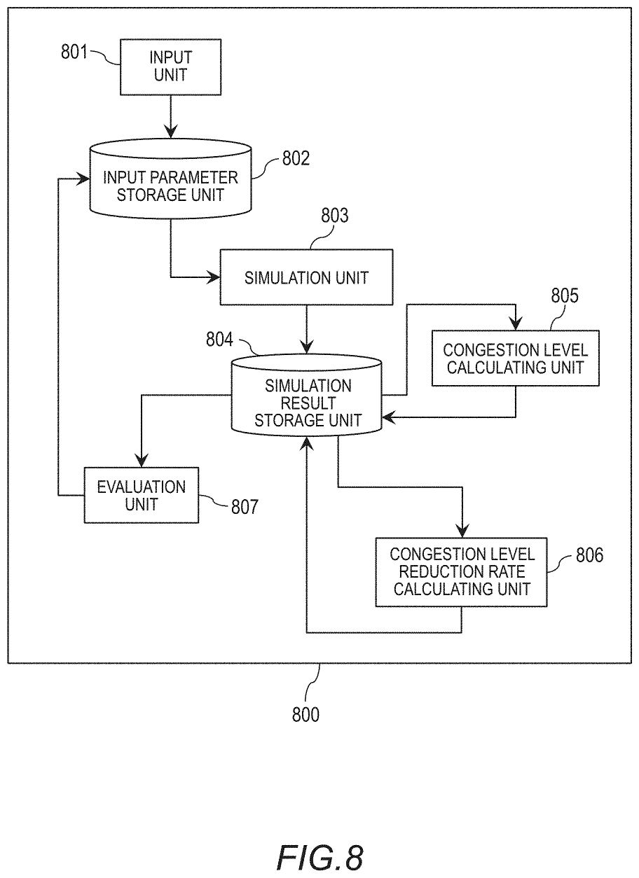

FIG. 8 is a diagram for explaining an example of the functional configuration and processes of the simulation device 800 in an embodiment of the present invention.

In this embodiment, as illustrated in FIG. 3A, the simulation program 309 and the simulation information 310 are stored in the storage device 302 of the computer 300 that realizes the operation management device 203. That is, the simulation device 800 of this embodiment is realized by the computer 300. Specifically, an input unit 801, a simulation unit 803, a congestion level calculation unit 805, a congestion level reduction rate calculation unit 806 and an evaluation unit 807 described below are the functions realized by the processor 301 controlling as necessary the input device 303, the output device 304, the communication IF 305, and the like according to the simulation program 309. In addition, an input parameter storage unit 802 and a simulation result storage unit 804, which will be described later, are provided as storage areas of the storage device 302, and the information stored in these areas is included in the simulation information 310.

However, the configuration described above is merely an example, and it is possible to realize the simulation device 800 having other configurations than that described above. For example, it is possible to configure the simulation device 800 such that, by storing the simulation program 309 and the simulation information 310 in the storage device 352 of the computer 350 that realizes the order management device 202, the computer 350 realizes the simulation device 800. Alternatively, another computer (not shown in the figure) differing from the computer 300 or the computer 350 may realize the simulation device 800. The functions of the simulation device 800 may also be realized by processes distributed among a plurality of computers (not shown in the figure). The simulation device 800 may be interpreted as a simulation system, and as described above, the functions of the simulation system may be realized by one or a plurality of computers.

The input unit 801 stores parameters inputted through the user interface illustrated in FIG. 6 or a relevant method into the input parameter storage unit 802. The parameters inputted here may include, for example, the initial value of the estimated reduction rate, the layout of the warehouse in which the simulation is performed, the initial position of each automatic guided vehicle AC in the simulation, the conveyance task used in the simulation, and the like.

The simulation unit 803 simulates the conveyance and picking work of the storage rack DS using the automated guided vehicle AC in this embodiment while appropriately referring to the parameters stored in the input storage unit 602, and passes the simulation results to the simulation result storage unit 804. The simulation of conveyance of the storage rack DS is performed in a manner illustrated in FIG. 5, for example.

The congestion level calculation unit 805 calculates the congestion level of the route by referring to the travel history of the automated guided vehicle AC accumulated in the simulation result storage unit 804, and stores the congestion level in the simulation result storage unit 804. The congestion level reduction rate calculation unit 806 calculates the congestion level reduction rate by referring to the congestion level and time information in the simulation result storage unit 804, and stores the congestion level reduction rate in the simulation result storage unit 804.

The evaluation unit 807 refers to the congestion level reduction rate in the simulation result storage unit 804, calculates an estimated reduction rate as a new input parameter, and stores it in the input parameter storage unit 802, thereby adaptively bringing the estimated reduction rate closer to an appropriate value. For example, the evaluation unit 807 may reflect the referenced congestion level reduction rate to the estimated reduction rate used as a new input parameter in accordance with the inputted result update rate. In this case, the evaluation unit 807 may obtain the estimated reduction rate used as a new input parameter by finding a weighted average of the referenced congestion level reduction rate and the estimated reduction rate at that time based on the result update rate, for example.

The estimated reduction rate used as a new input parameter calculated in this way may be stored in the input parameter storage unit 802, overwriting the estimated reduction rate used as the input parameter in the previous simulation, or may be added to the input parameter storage unit 802, keeping the previous estimated reduction rate. In the time simulation, the estimated reduction rate that is a new input parameter is used.

The simulation device 800 repeats the process described above, and when a prescribed condition is met (for example, when the value of the estimated reduction rate has converged, or when the number of repetition or calculation time has reached a prescribed upper limit), the simulation device 800 ends the process, and acquires a final estimated reduction rate. The operation management device 203 searches for a route for the automated guided vehicle AC for a conveyance task generated based on an actual order, using the estimated reduction rate acquired in this manner, and controls the actual guided vehicle AC to move down the route.

The effects of the present invention apply to other embodiments than those described above. For example, the embodiment described above is for the movement of automated guided vehicles inside a warehouse or factor, but as other embodiments, the present invention may be applied to a case where forklifts that can be automatically controlled or bucket carriers inside of the automated warehouse are subjected to simulation. Alternatively, the simulation described above may be applied to a traffic system where the traffic of each vehicle on the roads is centrally controlled.

Embodiments of the present invention may include the following examples.

(1) For example, a simulation device of the present invention may include a simulation unit (the simulation unit 803, for example) that performs a simulation of movement of a plurality of moving bodies that each move along a route; a storage unit (the storage device 302, for example) that stores therein an estimated reduction rate that is an index representing a change over time in congestion level on the route of each of the plurality of moving bodies; a first calculation unit (the congestion level calculation unit 805, for example) that calculates a congestion level on the route of each of the plurality of moving bodies based on a result of the simulation; and a second calculation unit (the congestion level reduction rate calculation unit 806, for example) that calculates an index representing a change over time in the congestion level calculated by the first calculation unit.

With this configuration, it is possible to set an appropriate reduction rate such that an estimated reduction rate of a congestion level used as an input of simulation and a reduction rate of a congestion level in the simulation result become the same as each other. This allows for improvement of the efficiency of the conveyance system subjected to the simulation. For example, it is possible to prevent a decrease in efficiency caused by selecting a route that goes through an area where the congestion level is still high, or a route that avoids an area where the congestion level is already low.

(2) In (1) above, the simulation unit searches for a route for each of the moving bodies using a cost based on a congestion level calculated on the basis of the estimated reduction rate read out from the storage unit (S503, for example), and performs a simulation of movement on the searched route (FIG. 5, for example), and the simulation device may further include an evaluation unit (the evaluation unit 807, for example) that calculates an estimated reduction rate based on the index representing a change over time in the congestion level calculated by the second calculation unit, and stores the calculated estimated reduction rate in the storage unit.

With this configuration, it is possible to set an appropriate estimated reduction rate, which allows for improvement of the efficiency of the conveyance system subjected to the simulation.

(3) In (2) described above, the simulation device may further include an output unit (the output device 304, for example) that displays distribution (the heat map illustrated in FIG. 7, for example) of at least one of a congestion level calculated based on a result of the simulation and a congestion level calculated based on the estimated reduction rate in a space subjected to the simulation.

This makes it easier to compare the estimated congestion level in simulation with the actual congestion level to see the difference between the two.

(4) In (1) described above, the congestion level of a route is defined based on at least one of a time required for the moving body to move down the route and the number of moving bodies that travel on the route per unit time.

With this configuration, it is possible to calculate an appropriate congestion level for the cost used for route finding.

(5) In (1) described above, the simulation unit simulates movement of the plurality of moving bodies from a starting point (the position of the storage rack to be conveyed, for example) to an end point (the position of the work station, for example) that are randomly specified in a space subjected to the simulation.

With this configuration, it is possible to find an appropriate estimated reduction rate by keeping travel routes from being significantly uneven.

(6) In (1) described above, the plurality of moving bodies may be automated guided vehicles that each convey a rack that stores an item.

With this configuration, it is possible to apply the present invention to conveyance of items in a warehouse, factory, and the like.

(7) It is possible to configure a conveyance system (for example, the conveyance system 200) that includes the simulation device of (1) described above or a simulation system equivalent thereto, an order management device (for example, the order management device 202) that manages order information including shipping addresses of items and quantities to be shipped, and an operation management device (for example, the operation management device 203) that manages an operation of an automated guided vehicle by finding a route based on the congestion level calculated using an estimated reduction rate calculated by the simulation system, in order to convey a rack having items stored therein in accordance with the order information.

This way, the present invention can be applied to conveyance of items in a warehouse, factory, and the like, for example.

This invention is not limited to the embodiments described above, and includes various modification examples. For example, the above-mentioned embodiments have been described in detail for better understanding of this invention, but this invention is not necessarily limited to an invention having all the configurations described above. A part of the configuration of a given embodiment may be replaced with a configuration of another embodiment, or the configuration of another embodiment can be added to the configuration of a given embodiment. It is also possible to add, delete, and replace other configurations for a part of the configuration of each embodiment.

A part or all of each of the above-mentioned configurations, functions, processing modules, processing means, and the like may be implemented by hardware by being designed as, for example, an integrated circuit. Each of the above-mentioned configurations, functions, and the like may be implemented by software by a processor interpreting and executing a program for implementing each function. Information, such as the programs, tables, files, and the like for implementing each of the functions may be stored in a storage device such as a non-volatile semiconductor memory, a hard disk drive, or a solid state drive (SSD), or in a computer-readable non-transitory data storage medium, such as an IC card, an SD card, or a DVD.

The control lines and information lines are illustrated to the extent considered to be required for description, and not all the control lines and information lines on the product are necessarily illustrated. In practice, it may be considered that almost all components are coupled to each other.

What is claimed is:

1. A simulation device, comprising:
a simulation unit that performs a simulation of movement of a plurality of moving bodies each moving along a route;
a storage unit that stores therein an estimated reduction rate that is an index representing a change over time in congestion level of the route of each of the plurality of moving bodies;
a first calculation unit that calculates a congestion level of the route of each of the plurality of moving bodies based on a result of the simulation; and
a second calculation unit that calculates an index representing a change over time in congestion level calculated by the first calculation unit.

2. The simulation device according to claim 1, wherein the simulation unit searches for a route for each of the plurality of moving bodies using a cost based on the congestion level calculated on the basis of the estimated reduction rate read out from the storage unit, and performs a simulation of movement on the searched route, and
wherein the simulation device further comprises an evaluation unit that calculates an estimated reduction rate based on the index representing a change over time in congestion level calculated by the second calculation unit, and stores the calculated estimated reduction rate in the storage unit.

3. The simulation device according to claim 2, further comprising an output unit that displays distribution of at least one of a congestion level calculated based on a result of the simulation and a congestion level calculated based on the estimated reduction rate in a space subjected to the simulation.

4. The simulation device according to claim 1, wherein the congestion level of the route is defined based on at least one of a time required for one of the moving bodies to move down the route and the number of moving bodies that travel on the route per unit time.

5. The simulation device according to claim 1, wherein the simulation unit simulates movement of the plurality of moving bodies from a starting point to an end point that are randomly specified in a space subjected to the simulation.

6. The simulation device according to claim 1, wherein the plurality of moving bodies are automated guided vehicles that each convey a rack that stores an item.

7. A simulation system, comprising:
a simulation unit that performs a simulation of movement of a plurality of moving bodies each moving along a route;
a storage unit that stores therein an estimated reduction rate that is an index representing a change over time in congestion level of the route of each of the plurality of moving bodies;
a first calculation unit that calculates a congestion level of the route of each of the plurality of moving bodies based on the simulation; and
a second calculation unit that calculates an index representing a change over time in the congestion level calculated by the first calculation unit.

8. The simulation system according to claim 7, wherein the simulation unit searches for a route for each of the plurality of moving bodies using a cost based on the congestion level calculated on the basis of the estimated reduction rate read out from the storage unit, and performs a simulation of movement on the searched route, and
wherein the simulation system further includes an evaluation unit that calculates an estimated reduction rate based on the index representing a change over time in congestion level calculated by the second calculation unit, and stores the calculated estimated reduction rate in the storage unit.

9. The simulation system according to claim 8, further comprising an output unit that displays distribution of at least one of a congestion level calculated based on a result of the simulation and a congestion level calculated based on the estimated reduction rate in a space subjected to the simulation.

10. The simulation system according to claim 7, wherein the congestion level of a route is defined based on at least one of a time required for the moving body to move down the route and the number of moving bodies that travel on the route per unit time.

11. The simulation system according to claim 7, wherein the simulation unit simulates movement of the plurality of moving bodies from a starting point to an end point that are randomly specified in a space subjected to the simulation.

12. The simulation system according to claim 7, wherein the plurality of moving bodies are automated guided vehicles that each convey a rack that stores an item.

13. A conveyance system, comprising:
the simulation system according to claim 12;
an order management device that manages order information including a shipping address of the item and a quantity to be shipped; and
an operation management device that manages an operation of the automated guided vehicles by finding routes based on a congestion level calculated using the estimated reduction rate obtained by the simulation system, in order to convey a rack that stores the item in accordance with the order information.

14. A simulation method performed by a simulation system including a processor and a storage unit that has stored therein an estimated reduction rate that is an index representing a change over time in congestion level of a route for each of a plurality of moving bodies, the simulation method, comprising:
a first step in which the processor performs a simulation of the plurality of moving bodies each moving along a route;
a second step in which the processor calculates a congestion level of the route of each of the plurality of moving bodies based on the simulation; and
a third step in which the processor calculates an index representing a change over time in the congestion level calculated in the second step.
